(19) United States
(12) Patent Application Publication
(10) Pub. No.: US 2025/0201158 A1
(43) Pub. Date: Jun. 19, 2025

(54) PIXEL CIRCUIT AND DISPLAY APPARATUS INCLUDING THE SAME

(71) Applicant: LG Display Co., Ltd., Seoul (KR)

(72) Inventors: Seung Hwan SHIN, Paju-si (KR); Hwa Young KIM, Paju-si (KR)

(21) Appl. No.: 18/967,163

(22) Filed: Dec. 3, 2024

(30) Foreign Application Priority Data
Dec. 13, 2023 (KR) 10-2023-0180885

(51) Int. Cl. G09G 3/00; G09G 3/3233; H10K 59/131; H10K 59/40

(52) U.S. Cl. CPC G09G 3/006; G09G 3/3233; H10K 59/131; H10K 59/40; G09G 2300/0819; G09G 2300/0852; G09G 2300/0861; G09G 2310/08; G09G 2320/045; G09G 2320/0626; G09G 2330/12

(57) ABSTRACT

A display apparatus, a pixel circuit and a controlling method of pixel circuit are disclosed. The display apparatus includes a display panel with a plurality of data lines, a plurality of gate lines, and a plurality of pixels disposed thereon, the display panel being configured to operate in a display mode for displaying an image and a sensing mode for sensing degradation of the pixels, a gate driver configured to supply a scan signal and an emission control signal to the plurality of gate lines, a data driver configured to supply a data signal to the plurality of data lines, a power supply configured to apply an initialization voltage to the pixels in the sensing mode, and a sensing unit configure to sense degradation of the pixels in the sensing mode.

### CROSS-REFERENCE TO RELATED APPLICATION(S)

This application claims the priority benefit of Korean Patent Application No. 10-2023-0180885, filed on Dec. 13, 2023, the entire contents of which are hereby expressly incorporated for all purposes.

### BACKGROUND

### Technical Field

The present disclosure relates to a display apparatus, and more particularly, for example, without limitation, to a display apparatus configured to enhance image quality through compensation for degradation of a light emitting element thereof.

### Description of the Related Art

Image display apparatuses, which render a variety of information on a screen, are core technologies of the information communication age, and are being developed toward further thinness, further lightness, greater portability, and higher performance. As such, display apparatuses, which may be manufactured to have a light and thin structure, are being highlighted.

Such a display apparatus is self-luminous and, as such, is not only advantageous in terms of power consumption according to low-voltage driving, but also has fast response time, high luminous efficacy, wide viewing angle, and high contrast ratio. In this regard, such a display apparatus is being highlighted as a next-generation display apparatus and research thereon is being conducted. Such a display apparatus renders an image through a plurality of sub-pixels arranged in a matrix. Each of the plurality of sub-pixels includes a light emitting element, and a pixel circuit including a plurality of transistors configured to independently drive the light emitting element, etc.

As concrete examples of such a display apparatus, there are a liquid crystal display (LCD) apparatus, a quantum dot display (QD) apparatus, a field emission display (FED) apparatus, an organic light emitting display (OLED) apparatus, etc.

Among these display apparatuses, the OLED apparatus, which is highlighted as a means not requiring a separate light source while achieving compactness and high-definition color display, has advantages of fast response time, high contrast ratio, high luminous efficacy, high brightness, wide viewing angle, etc., through use of an organic light emitting diode (OLED) configured to emit light in a self-luminous manner.

Among the above-mentioned display apparatuses, the OLED apparatus, which includes the OLED, has various advantages because an image is displayed based on light emitted from a light emitting element in a pixel.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### BRIEF SUMMARY

The inventors have recognized that, in the OLED apparatus of the related art, an image quality degradation phenomenon such as color coordinate change or the like may often occur during driving. This may result in degradation of high image quality to be basically satisfied in a display apparatus including OLED elements.

The present disclosure provides a pixel circuit and a display apparatus including the same that, among others, substantially obviate one or more problems due to limitations and disadvantages of the related art.

The present disclosure relates to a display apparatus including a pixel circuit including a transistor configured to receive a sensing signal while being configured to compensate for degradation of a light emitting element through sensing of the degradation, thereby enhancing image quality.

As embodied and broadly described herein, a display apparatus comprises a plurality of data lines, a plurality of gate lines, and a plurality of pixels disposed thereon, the display panel being configured to operate in a display mode for displaying an image and a sensing mode for sensing degradation of the pixels, a gate driver configured to supply a scan signal and an emission control signal to the plurality of gate lines, a data driver configured to supply a data signal to the plurality of data lines, a power supply configured to apply an initialization voltage to the pixels in the sensing mode, and a sensing unit configured to sense degradation of the pixels in the sensing mode.

In another aspect of the present disclosure, a pixel circuit includes a light emitting element, a capacitor connected between a first node and a second node, a first transistor including a first electrode connected to a reference voltage line and a second electrode connected to the first node, the first transistor being configured to supply a reference voltage to the first node in response to an emission control signal of an n+1-th pixel row, a second transistor including a first electrode connected to the reference voltage line and a second electrode connected to the second node, the second transistor being configured to supply the reference voltage to the second node in response to a scan signal of an n−1-th pixel row, a driving transistor including a gate electrode connected to the second node, a first electrode configured to receive a high-level drive voltage and a second electrode connected to a third node, a third transistor including a first electrode connected to an initialization voltage line and a second electrode connected to a fourth node, the third transistor being configured to supply an initialization voltage to the fourth node in response to a scan signal of an n-th pixel row, and a fourth transistor including a first electrode connected to the initialization voltage line and a second electrode connected to the fourth node, the fourth transistor being configured to be turned on in response to a sensing signal.

In another aspect of the present disclosure, a controlling method of pixel circuit according to the exemplary embodiment of the present disclosure may comprises: supplying a reference voltage to a first node via a first transistor in response to an emission control signal of an n+1-th pixel row, the first transistor comprising a first electrode connected to a reference voltage line and a second electrode connected to the first node; supplying the reference voltage to a second node via a second transistor in response to a scan signal of an n−1-th pixel row, the second transistor comprising a first electrode connected to the reference voltage line and a second electrode connected to the second node; receiving a high-level drive voltage via a driving transistor, the driving transistor comprising a first electrode receiving the high-level drive voltage, and a second electrode connected to a third node, and a gate electrode connected to the second node; supplying an initialization voltage to a fourth node via a third transistor in response to a scan signal of an n-th pixel row, the third transistor comprising a first electrode connected to an initialization voltage line and a second electrode connected to the fourth node; and turning on a fourth transistor in response to a sensing signal, the fourth transistor comprising a first electrode connected to the initialization voltage line and a second electrode connected to the fourth node, wherein a first capacitor is connected between the first node and the second node.

Technical features of the present disclosure are not limited to the above-described object, and other technical features and characteristics of the present disclosure not yet described will be more clearly understood by those skilled in the art from the following detailed description.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a block diagram of a display apparatus according to an exemplary embodiment of the present disclosure;

FIG. 2 is a cross-sectional view showing a stack structure of a display apparatus according to an exemplary embodiment of the present disclosure;

FIG. 3 is a block diagram showing a configuration of a gate driver in a display apparatus according to an exemplary embodiment of the present disclosure;

FIG. 4 is circuit diagram showing a pixel circuit in a display apparatus according to an exemplary embodiment of the present disclosure;

FIG. 5 is a diagram depicting operation waveforms of the pixel circuit shown in FIG. 4 in a display mode of the display apparatus according to the exemplary embodiment of the present disclosure;

FIG. 6 is a diagram depicting operation waveforms in an active period in which the display mode operates and a blank period in which a sensing mode operates, for one frame, in the display apparatus according to the exemplary embodiment of the present disclosure;

FIGS. 7A and 7B are diagrams showing a configuration of a controller including a sensing unit in the display apparatus according to the exemplary embodiment of the present disclosure; and

FIG. 8 is a graph depicting a lifespan brightness in the display apparatus according to the exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Improvements and features of the present disclosure and methods for achieving the same will be made clear from embodiments described below in detail with reference to the accompanying drawings. The present disclosure may, however, be embodied in many different forms, and should not be construed as being limited to the embodiments set forth herein. Here, embodiments of the present disclosure are provided so that the present disclosure may be sufficiently thorough and complete to assist those skilled in the art in fully understanding the scope of the present disclosure.

The shape, size, ratio, angle, number and the like shown in the drawings to illustrate the embodiments of the present disclosure are only for illustration and are not limited to the contents shown in the drawings. Wherever possible, the same reference numbers will be used throughout the drawings to refer to the same or like parts. In the following description, detailed descriptions of technologies or configurations related to the present disclosure may be omitted so as not to unnecessarily obscure the subject matter of the present disclosure.

When terms such as “include,” “have,” “comprise,” “contain,” “constitute,” “make up of,” “formed of,” and “consist of” are used throughout the specification, an additional component may be present, unless “only” is used. A component described in a singular form encompasses components in a plural form unless particularly stated otherwise.

The shapes, sizes, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It should be interpreted that the components included in the exemplary embodiment of the present disclosure include an error range, although there is no additional particular description thereof.

In describing a variety of embodiments of the present disclosure, when terms for positional relationship such as “on”, “above”, “over”, “below”, “under”, “beside”, “beneath”, “near”, “close to,” “adjacent to”, “on a side of”, “next” are used, at least one intervening element may be present between two elements unless “immediately” or “directly” is used.

Spatially relative terms, such as “under,” “below,” “beneath,” “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below.”

When an element or layer is disposed “on” another element or layer, another layer or another element may be interposed directly on the other element or therebetween.

When a temporal relationship is described, for example, when terms for temporal relationship of events such as “after,” “subsequently,” “next,” and “before” are used, there may also be the case in which the events are not continuous, unless “immediately” or “directly” is used.

In the meantime, although terms including an ordinal number, such as first or second, may be used to describe a variety of constituent elements, the constituent elements are not limited to the terms, and the terms are used only for the purpose of discriminating one constituent element from other constituent elements. Accordingly, a first constituent element may represent a second constituent element within the scope of the present disclosure.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

A term “apparatus” used herein may refer to a display apparatus including a display panel and a driver for driving the display panel. Examples of the display apparatus may include a light emitting element, and the like. In addition, examples of the apparatus may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The respective features of various embodiments according to the present disclosure can be partially or entirely joined or combined and technically variably related or operated, and the embodiments can be implemented independently or in combination.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, embodiments of the present disclosure will be described with reference to the accompanying drawings. In the specification, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

Hereinafter, various embodiments of the present disclosure will be described in detail with reference to the accompanying drawings.

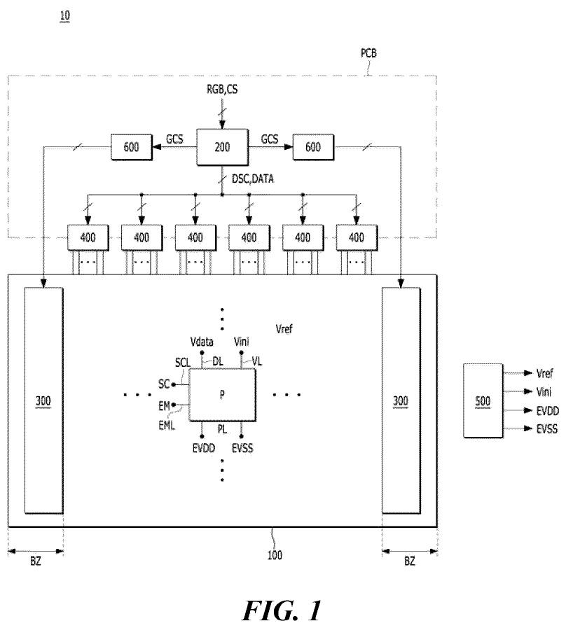

FIG. 1 is a block diagram of a display apparatus according to an exemplary embodiment of the present disclosure.

Referring to FIG. 1, the display apparatus according to the exemplary embodiment of the present disclosure, which is designated by reference numeral “10”, includes a display panel 100 including a plurality of pixels P, a controller 200, a gate driver 300 configured to supply a gate signal to each of the plurality of pixels P, a data driver 400 configured to supply a data signal to each of the plurality of pixels P, a power supply 500 configured to supply electric power to each of the plurality of pixels P, for driving of each of the plurality of pixels P, a level shifter 600 configured to adjust a potential of a gate signal applied to the gate driver 300, and a sensing unit 700 configured to sense degradation of the plurality of pixels P.

Here, the controller 200, the gate driver 300, the data driver 400, and the sensing unit 700 may be collectively referred to as a “control unit”.

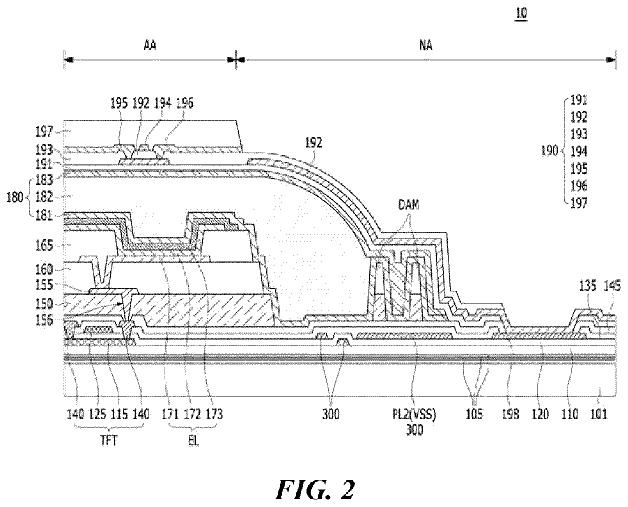

The display panel 100 includes an active area (AA) (cf. FIG. 2) in which the pixels P are disposed, and a non-active area (NA) (cf. FIGS. 2 to 4) disposed to surround the active area (AA). In the non-active area (NA), the gate driver 300 and the data driver 400 are disposed.

A plurality of gate lines GL and a plurality of data lines DL intersect each other at the display panel 100, and each of the plurality of pixels P is connected to corresponding ones of the gate lines GL and the data lines DL. In detail, each pixel P receives a gate signal from the gate driver 300 through the corresponding gate line GL, receives a data signal from the data driver 400 through the corresponding data line DL, and receives a high-level drive voltage EVDD and a low-level drive voltage EVSS from the power supply 500 through drive voltage lines PL.

Each gate line GL supplies a scan signal SC and an emission control signal EM, and each data line DL supplies a data voltage Vdata. In accordance with various embodiments, each gate line GL may include a plurality of scan lines SCL for supply of the scan signal SC, and a plurality of emission control signal lines EML for supply of the emission control signal EM. In addition, the plurality of pixels P additionally includes power lines VL and, as such, may receive a reference voltage Vref and an initialization voltage Vini.

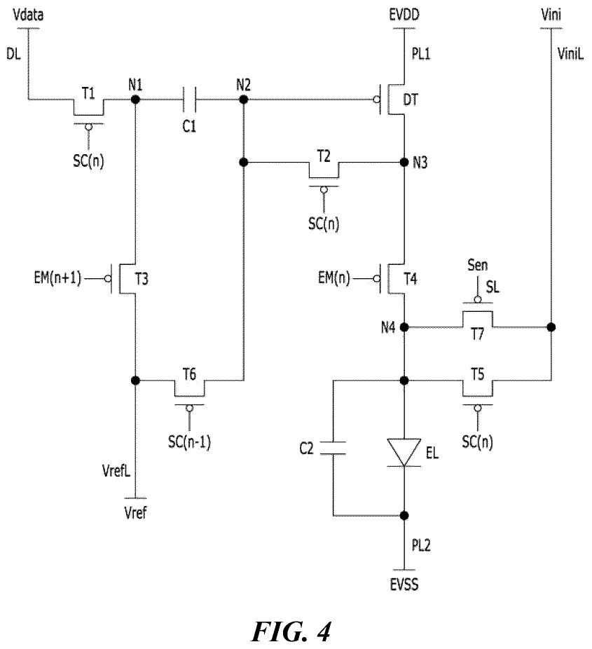

In addition, as shown in FIGS. 2 and 4, each pixel P includes a light emitting element EL, and a pixel circuit configured to control driving of the light emitting element EL. In this case, the light emitting element EL is constituted by an anode 171, a cathode 173, and an emission layer 172 disposed between the anode 171 and the cathode 173.

The pixel circuit includes a plurality of switching elements, a driving element, and a capacitor. In this case, each of the switching elements and the driving element may be constituted by a thin film transistor.

Active layers of the thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

In the pixel circuit, the driving element adjusts a light emission amount of the light emitting element EL by controlling an amount of current supplied to the light emitting element EL in accordance with a data voltage Vdata.

In addition, the plurality of switching elements receives respective scan signals SC supplied through a plurality of scan lines SCL and an emission control signal EM supplied through an emission control line EML, thereby operating the pixel circuit.

The display panel 100 may be implemented as a non-transmissive display panel or a transmissive display panel. The transmissive display panel may be applied to a transparent display apparatus in which an image is displayed on a screen and through which an actual background is visible. The display panel 100 may be implemented as a flexible display panel. The flexible display panel may be implemented as an organic light emitting display panel using a plastic substrate. For example, the substrate may include a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

Each of the plurality of subpixels SP is a unit which configures the display area and n subpixels SP form one pixel. Each of the plurality of subpixels SP may emit light having different wavelengths from each other. The plurality of subpixels may include first to third subpixels which emit different color light from each other. Each pixel P may be divided into a red subpixel, a green subpixel, and a blue subpixel, for color rendering. Each pixel P may further include a white subpixel. The plurality of subpixels SP may be variously modified in colors and configurations, as necessary. However, the present disclosure is not limited thereto.

For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

Each pixel P may include a pixel circuit. For example, the pixel circuit of each of the plurality of subpixels may include a capacitor, at least one thin film transistor, and a light emitting element. For example, the at least one thin film transistor may include a driving transistor, a first switching transistor, and a second switching transistor. In addition, the light emitting element may include a first electrode (or anode electrode, pixel electrode), a light emitting layer (or organic light emitting layer), and a second electrode (or cathode electrode, common electrode). However, the pixel circuit of each of the plurality of subpixels are not limited thereto, each of the plurality of subpixels may further include a compensation circuit. In this case, each of the plurality of subpixels may have various structures such as 4T2C, 5T2C, 6T1C, 6T2C, 7T1C, 7T2C, and the like.

Touch sensors may be disposed on the display panel 100. Touch input may be sensed using separate touch sensors or may be sensed through pixels P. The touch sensors may be disposed on a screen of the display panel 100 in an on-cell type or an add-on type or may be implemented as in-cell type touch sensors built in the display panel 100.

The controller 200 processes image data RGB input thereto from an outside thereof, to match the size and resolution of the display panel 100, and then supplies the processed image data RGB to the data driver 400.

The controller 200 generates a gate control signal GCS and a data control signal DCS using timing signals CS input from the outside thereof, for example, a dot clock signal CLK, a date enable signal DE, a horizontal synchronization signal Hsync, and a vertical synchronization signal Vsync. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel. The controller 200 supplies the gate control signal GCS and the data control signal DCS generated as described above to the gate driver 300 and the data driver 400, respectively, thereby controlling the gate driver 300 and the data driver 400.

The controller 200 may be configured to be coupled with various processors, for example, a microprocessor, a mobile processor, an application processor, etc., in accordance with a device mounted therein.

A host system, which is applied to the controller 200, may be one of a television (TV) system, a set-top box, a navigation system, a personal computer (PC), a home theater system, a mobile appliance, a wearable appliance, and a vehicle system.

The controller 200 may multiply an input frame frequency by i times, thereby controlling operation timings of the display panel drivers at a frame frequency corresponding to an “input frame frequency x i” Hz (i being a positive integer greater than 0). The input frame frequency is 60 Hz in a national television standards committee (NTSC) system, and is 50 Hz in a phase-alternating line (PAL) system.

The controller 200 may generate signals in order to enable each pixel P to be driven at various refresh rates. That is, the controller 200 may generate signals associated with driving of each pixel P in order to enable the pixel P to be driven in a variable refresh rate (VRR) mode or to be switched between a first refresh rate and a second refresh rate. For example, the controller 200 may drive each pixel P at various refresh rates by simply varying a rate of a clock signal, generating a synchronization signal, for generation of a horizontal blank or a vertical blank, or driving the gate driver 300 in a mask manner.

The controller 200 generates the gate control signal GCS for control of an operation timing of the gate driver 300 and the data control signal DCS for control of an operation timing of the data driver 400 based on the timing signals CS received from the host system. The controller 200 synchronizes the gate driver 300 and the data driver 400 with each other by controlling the operation timings of the display panel drivers.

The data driver 400 receives image data DATA and the data control signal DCS from the controller 200. The data driver 400 converts the image data DATA into a gamma compensation voltage in response to the data control signal DCS from the controller 200, thereby generating a data voltage Vdata, and then supplies the data voltage Vdata to the data lines DL of the display panel 100 in synchronization with a scan signal SC. The data driver 400 may be connected to the data lines of the display panel 100 through a chip-on-glass (COG) process or a tape automated bonding (TAB) process.

The gate driver 300 operates in accordance with a gate control signal GCS input thereto from the level shifter 600, thereby generating a gate signal. In addition, the gate driver 300 sequentially supplies the gate signal to the gate lines GL. The gate driver 300 may be directly formed on a lower substrate of the display panel 100 in a gate driver-in-panel (GIP) manner.

The gate driver 300 may be formed in the non-active area NA of the display panel 100 outside the active area AA on which a screen is displayed. The non-active area NA may be an area adjacent to the active area AA. Further, the non-active area NA may be an area disposed adjacent to the active area AA and configured to surround the active area AA. However, the present disclosure is not limited thereto.

For example, the non-active area NA may include a first non-display area located outside the active area AA in a first direction, a second non-display area located outside the active area AA in a second direction intersecting the first direction, a third non-display area located outside the active area AA in the opposite direction to the first direction, and a fourth non-display area located outside the active area AA in the direction opposite to the second direction.

For another example, a boundary area between the active area AA and the non-active area NA may be bent so that the non-active area NA may be located below the display area. In this case, when the user looks at the display device from the front, there may be little or no non-active area NA visible to the user.

The non-active area NA may include a bezel area BZ or may be identical to the bezel area BZ. In a GIP structure, the level shifter 600 may be mounted on a printed circuit board (PCB), together with the controller 200.

The power supply 500 generates DC power for driving of a pixel array and the display panel drivers of the display panel 100, using a DC-DC converter. The DC-DC converter may include a charge pump, a regulator, a buck converter, a boost converter, etc. The power supply 500 may receive a DC input voltage applied from a host system (not shown), thereby generating DC voltages such as a gate-on voltage VGL/VEL, a gate-off voltage VGH/VEH, a high-level drive voltage EVDD, a low-level drive voltage EVSS, etc. The gate-on voltage VGL/VEL and the gate-off voltage VGH/VEH are supplied to the level shifter 600 and the gate driver 300. The high-level drive voltage EVDD and the low-level drive voltage EVSS are supplied to the pixels P in common.

The level shifter 600 boosts a transistor-transistor-logic (TTL)-level voltage of the gate control signal GCS input thereto from the controller 200 to a gate-high voltage VGH or a gate-low voltage VGL capable of driving thin film transistors (TFTs) formed at the display panel 100, and then supplies the boosted voltage to the gate driver 300. The gate control signal GCS includes a start signal, a clock signal, etc.

FIG. 2 is a cross-sectional view showing a stack structure of a display apparatus according to an exemplary embodiment of the present disclosure.

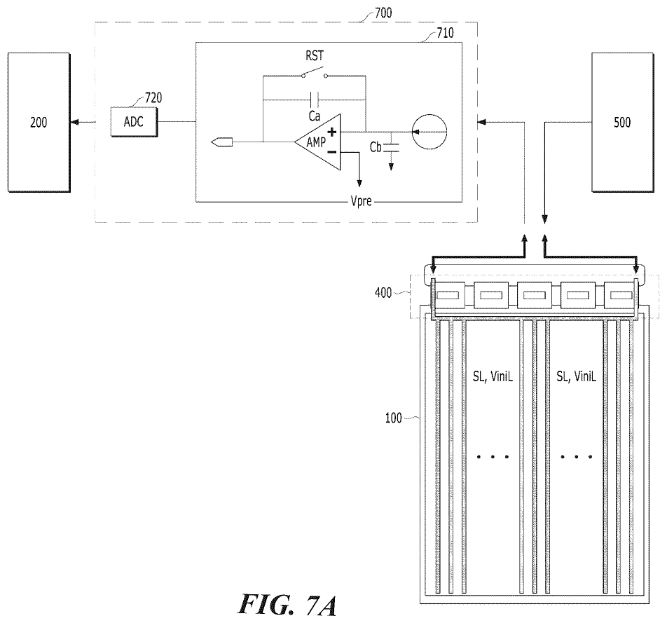

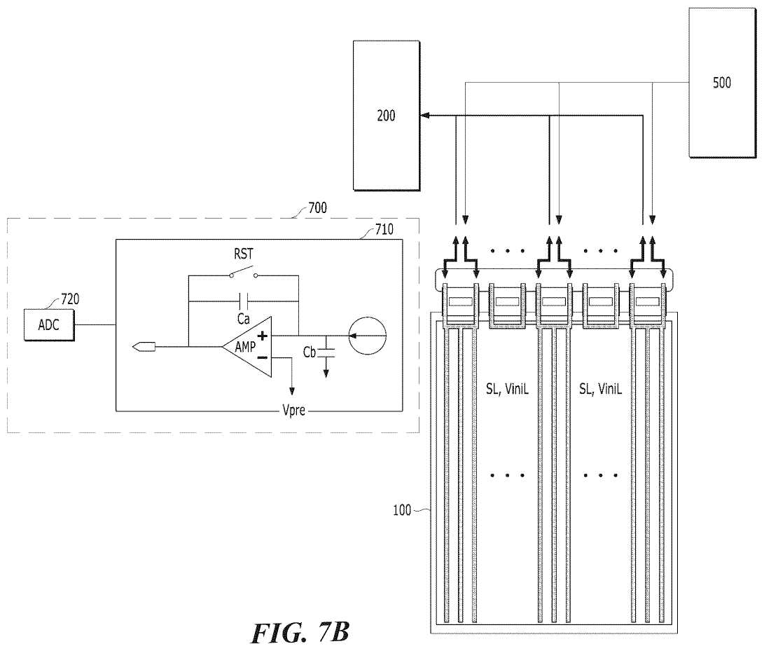

Referring to FIG. 2, a thin film transistor TFT configured to drive a light emitting element EL may be disposed on a substrate 101 in an active area AA. In FIG. 2, among various thin film transistors, which may be included in a display apparatus 10, only a driving transistor DT (FIGS. 7A and 7B) is shown for convenience of description. However, the thin film transistor TFT shown in FIG. 2 is not limited to the above-described condition. Although the thin film transistor TFT will be described in conjunction with an example in which the thin film transistor TFT has a coplanar structure, in the following description, the thin film transistor TFT may be implemented to have various structures such as a staggered structure, etc.

The driving transistor DT may control current supplied to the light emitting element EL based on a high-level drive voltage EVDD, corresponding to a data voltage Vdata supplied to a gate electrode 125 thereof. In accordance with such current control, the driving transistor DT may adjust a light emission amount of the light emitting element EL. In this case, a constant amount of current is supplied to the light emitting element EL by a voltage charged in a storage capacitor Cst until a data voltage Vdata of a next frame is supplied and, as such, a light emission state of the light emitting element EL may be maintained.

A high-level drive voltage line PL1 configured to supply the high-level drive voltage EVDD may be formed in parallel to a data line DL. The high-level drive voltage line PL1 and/or the data line DL may be formed on the same layer as a source or drain electrode 140 of the transistor TFT, using the same material as the source or drain electrode 140 of the transistor TFT, however, the present disclosure is not limited thereto. For example, the high-level drive voltage line PL1 and/or the data line DL may be formed using different materials from the source or drain electrode 140 of the transistor TFT, the high-level drive voltage line PL1 and/or the data line DL may also be formed on different layers from the source or drain electrode 140 of the transistor TFT.

The thin film transistor TFT may include a semiconductor layer 115 disposed on a first insulating layer 110, a gate electrode 125 overlapping with the semiconductor layer 115 under the condition that a second insulating layer 120 is interposed therebetween, and source and drain electrodes 140 formed on a third insulating layer 135 to contact the semiconductor layer 115.

The semiconductor layer 115 may be a region in which a channel is formed during driving of the thin film transistor TFT. The semiconductor layer 115 may be formed of an oxide semiconductor or may be formed of various organic semiconductors such as amorphous silicon (a-Si), polycrystalline silicon (poly-Si), pentacene, etc., without being limited thereto.

The semiconductor layer 115 may be formed on the first insulating layer 110. The semiconductor layer 115 may include a channel region, a source region, and a drain region. The semiconductor layer 115 may overlap with the gate electrode 125 under the condition that the second insulating layer 120 is interposed therebetween, thereby forming the channel region between the source and drain electrodes 140. The source region is electrically connected to the source electrode 140 through a contact hole extending through the second insulating layer 120 and the third insulating layer 135. The drain region is electrically connected to the drain electrode 140 through a contact hole extending through the second insulating layer 120 and the third insulating layer 135.

A buffer layer 105 and the first insulating layer 110 may be disposed between the semiconductor layer 115 and the substrate 101. The buffer layer 105 may delay diffusion of moisture and/or oxygen penetrating the substrate 101. The first insulating layer 110 may protect the semiconductor layer 115 and may block various kinds of defects introduced from the substrate 101.

An uppermost layer of the buffer layer 105 contacting the first insulating layer 110 may be formed of a material having etching characteristics different from those of remaining layers of the buffer layer 105, the first insulating layer 110, the second insulating layer 120, and the third insulating layer 135. The uppermost layer of the buffer layer 105 contacting the first insulating layer 110 may be formed of one of silicon nitride (SiNₓ) and silicon oxide (SiOₓ). The remaining layers of the buffer layer 105, the first insulating layer 110, the second insulating layer 120, and the third insulating layer 135 may be formed of the remaining one of silicon nitride (SiNₓ) and silicon oxide (SiOₓ). For example, the uppermost layer of the buffer layer 105 contacting the first insulating layer 110 may be formed of silicon nitride (SiNₓ), whereas the remaining layers of the buffer layer 105, the first insulating layer 110, the second insulating layer 120, and the third insulating layer 135 may be formed of silicon oxide (SiOₓ). For example, the uppermost layer of the buffer layer 105 contacting the first insulating layer 110 may be formed of silicon oxide (SiOₓ), whereas the remaining layers of the buffer layer 105, the first insulating layer 110, the second insulating layer 120, and the third insulating layer 135 may be formed of silicon nitride (SiNₓ). Of course, the present disclosure is not limited to the above-described conditions.

The gate electrode 125 may be formed on the second insulating layer 120, and may overlap with the channel region of the semiconductor layer 115 under the condition that the second insulating layer 120 is interposed therebetween. The gate electrode 125 may be formed of a first conductive material constituted by one of molybdenum (Mo), aluminum (Al), chromium (Cr), gold (Au), titanium (Ti), nickel (Ni), neodymium (Nd) and copper (Cu), or an alloy thereof while having a single-layer structure or a multilayer structure, without being limited thereto.

The source electrode 140 may be connected to the source region of the semiconductor layer 115 exposed through the contact hole extending through the second insulating layer 120 and the third insulating layer 135. The drain electrode 140 may face the source electrode 140, and may be connected to the drain region of the semiconductor layer 115 through the contact hole extending through the second insulating layer 120 and the third insulating layer 135. The source and drain electrodes 140 as described above may be formed of a second conductive material constituted by one of molybdenum (Mo), aluminum (Al), chromium (Cr), gold (Au), titanium (Ti), nickel (Ni), neodymium (Nd) and copper (Cu), or an alloy thereof while having a single-layer structure or a multilayer structure, without being limited thereto. The second conductive material may be same as or different from the first conductive material. For example, the first conductive material includes one of molybdenum (Mo), aluminum (Al), chromium (Cr), gold (Au), titanium (Ti), nickel (Ni), neodymium (Nd) and copper (Cu), or an alloy thereof, and the second conductive material is same as the first conductive material. For example, the first conductive material includes one of molybdenum (Mo), aluminum (Al), chromium (Cr), gold (Au), titanium (Ti), nickel (Ni), neodymium (Nd) and copper (Cu), or an alloy thereof, while the second conductive material includes another one of molybdenum (Mo), aluminum (Al), chromium (Cr), gold (Au), titanium (Ti), nickel (Ni), neodymium (Nd) and copper (Cu), or an alloy thereof, which is different from the one. However, the present disclosure is not limited thereto.

A connection electrode 155 may be disposed between a first intermediate layer 150 and a second intermediate layer 160. The connection electrode 155 may be exposed through a connection electrode contact hole 156 extending through the protective layer 145 and the first intermediate layer 150 and, as such, may be connected to the drain electrode 140. The connection electrode 155 may be made of a material having low resistivity, identically or similarly to the drain electrode 150, without being limited thereto.

The light emitting element EL, which includes an emission layer 172, may be disposed on the second intermediate layer 160 and a bank layer 165. The light emitting element EL may include an anode 171, at least one emission layer 172 formed on the anode 171, and a cathode 173 formed on the emission layer 172.

The anode 171 may be disposed on the first intermediate layer 150 through the contact hole extending through the second intermediate layer 160, and may be electrically connected to the connection electrode 155 exposed upwardly of the second intermediate layer 160.

The anode 171 can be formed of a metal material having high reflectance, such as a stacked structure Ti/Al/Ti of aluminum and titanium, a stacked structure ITO/AI/ITO of aluminum and ITO, an Ag alloy, a stacked structure ITO/Ag alloy/ITO of Ag alloy and ITO, MoTi alloy, and a stacked structure ITO/MoTi alloy/ITO of MoTi alloy and ITO. The Ag alloy can be an alloy of silver Ag, palladium Pd, and copper Cu. The MoTi alloy can be an alloy of molybdenum Mo and titanium Ti. However, the present disclosure is not limited thereto.

In each pixel, the anode 171 is formed to be exposed by the bank layer 165. The bank layer 165 may be formed of an opaque material (for example, black) in order to prevent light interference between adjacent pixels. In this case, the bank layer 165 may include a light shielding material constituted by at least one of a color pigment, organic black, or carbon, without being limited thereto.

For example, the bank layer 165 can be formed of an organic layer such as an acryl-based material, an epoxy-based material, a phenolic-based material, a polyamide-based material, or a polyimide-based material. Meanwhile, the bank layer 165 may include an inorganic insulating material, such as silicon nitride (SiNₓ) or silicon oxide (SiOₓ), or the bank layer 165 may be formed of black resin. However, the present disclosure is not limited thereto.

The bank layer 165 can cover the edge of each of the anodes 171 and can be formed to expose a portion of each of the anodes 171. Accordingly, the bank layer 165 can prevent a current from being concentrated at an end of each of the anodes 171 so that it is possible to prevent a deterioration of light emitting efficiency.

At least one emission layer 172 may be formed on the anode 171 in the emission region provided by the bank layer 165. The at least one emission layer 172 may include a hole transport layer, a hole injection layer, a hole blocking layer, the emission layer 172, an electron injection layer, an electron blocking layer, an electron transport layer, etc., on the anode 171, and these layers may be formed through sequential stacking thereof in a normal order or a reverse order according to an emission direction. In addition, the emission layer 172 may be provided at first and second emission stacks facing each other under the condition that a charge generation layer is interposed therebetween. In this case, the emission layer 172 of one of the first and second emission stacks may generate blue light, and the emission layer 172 of the remaining one of the first and second emission stacks may generate yellow-green light and, as such, white light may be generated through the first and second emission stacks. The white light generated from the emission stacks may be incident upon a color filter disposed over or under the emission layer 172 and, as such, a color image may be rendered.

In another example, a color image may be rendered as color light corresponding to each subpixel is generated in each emission layer 172, without provision of a separate color filter. For example, the emission layer 172 of a red subpixel may generate red light, the emission layer 172 of a green subpixel may generate green light, and the emission layer 172 of a blue subpixel may generate blue light. However, the present disclosure is not limited thereto.

The cathode 173 may be formed to face the anode 171 under the condition that the emission layer 172 is interposed therebetween, and may receive a high-level drive voltage EVDD.

The cathode 173 can be formed of a transparent conductive material TCO capable of transmitting light therethrough such as indium tin oxide ITO and indium zinc oxide IZO, or a semi-transmissive conductive material such as magnesium Mg, silver Ag, or an alloy of magnesium Mg and silver Ag. However, the present disclosure is not limited thereto. When the cathode 173 is formed of a semi-transmissive metal material, a light emission efficiency can be increased by a microcavity.

An encapsulation layer 180 may prevent penetration of external moisture or oxygen into the light emitting element EL weak against the external moisture or oxygen. To this end, the encapsulation layer 180 may include an inorganic encapsulation layer constituted by at least one layer and an organic encapsulation layer constituted by at least one layer, without being limited thereto. In the following description, the encapsulation layer 180 will be described in conjunction with, for example, a structure in which a first encapsulation layer 181, a second encapsulation layer 182, and a third encapsulation layer 183 are sequentially stacked.

The first encapsulation layer 181 is formed on the substrate 101 formed with the cathode 173. The third encapsulation layer 183 is formed on the substrate 101 formed with the second encapsulation layer 182. The third encapsulation layer 183 may be formed to surround an upper surface, a lower surface, and side surfaces of the second encapsulation layer 182, together with the first encapsulation layer 181. The first encapsulation layer 181 and the third encapsulation layer 183 as described above may minimize or reduce penetration of external moisture or oxygen into the light emitting element EL. The first encapsulation layer 181 and the third encapsulation layer 183 may be formed of an inorganic insulating material enabling low-temperature deposition thereof, such as silicon nitride (SiNₓ), silicon oxide (SiOₓ), silicon oxynitride (SiON), or aluminum oxide (Al₂O₃). Since the first encapsulation layer 181 and the third encapsulation layer 183 are deposited in a low-temperature atmosphere, it may be possible to prevent the light emitting element EL, which is weak against a high-temperature atmosphere, from being damaged in deposition processes for the first encapsulation layer 181 and the third encapsulation layer 183.

The second encapsulation layer 182 may have a buffering function for reducing stress between layers caused by bending of the display apparatus 10, and may planarize a step between the layers. The second encapsulation layer 182 may be formed on the substrate 101 formed with the first encapsulation layer 181, using a non-photosensitive organic insulating material such as acryl resin, epoxy resin, phenolic resin, polyamide resin, polyimide resin, polyethylene, or silicon oxycarbide (SiOC) or a photosensitive organic insulating material such as photoacryl, without being limited thereto.

When the second encapsulation layer is formed in an ink-jet manner, a dam DAM may be disposed in order to prevent the second encapsulation layer 182, which has a liquid phase, from being diffused to an edge of the substrate 101. The dam DAM may be disposed nearer to the edge of the substrate 101 than the second encapsulation layer 182. By virtue of the dam DAM as described above, it may be possible to prevent the second encapsulation layer 182 from being diffused to a pad area in which a conductive pad at an outermost portion of the substrate 101 is disposed.

Although the dam DAM is designed to prevent diffusion of the second encapsulation layer 182, the second encapsulation layer 182, which is an organic layer, may be outwardly exposed when the second encapsulation layer 182 is formed to overflow the height of the dam DAM in execution of a process associated therewith and, as such, moisture, etc., may easily penetrate the light emitting element. In order to prevent such a phenomenon, accordingly, the dam DAM may be formed such that at least ten dams are formed in an overlapping manner.

The dam DAM may be disposed on a protective layer 145 in the non-active area NA. In addition, the dam DAM may be formed simultaneously with the first intermediate layer 150 and the second intermediate layer 160. A lower layer of the dam DAM may be formed together with the first intermediate layer 150 when the first intermediate layer 150 is formed, and an upper layer of the dam DAM may be formed together with the second intermediate layer 160 when the second intermediate layer 160 is formed, and, as such, the dam DAM may be formed to have a double stack structure.

Accordingly, the dam DAM may be constituted by materials identical to those of the first intermediate layer 150 and the second intermediate layer 160, without being limited thereto. For example, the dam DAM may be formed separately. The dam DAM may be constituted by materials different from those of the first intermediate layer 150 and the second intermediate layer 160.

The dam DAM may be formed to overlap with a low-level drive voltage line PL2. For example, the low-level drive voltage line PL2 may be formed at a lower layer in a region where the dam DAM is disposed, in the non-active area NA.

Alternatively, the encapsulation layer 180 includes a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer 180 is not limited to three or five layers, for example, n layers alternately stacked between inorganic encapsulation layer and organic encapsulation layer (where n is an integer greater than 3) may be included.

The low-level drive voltage line PL2 and the gate driver 300, which is configured in a GIP type, are formed to surround a periphery of the display panel. The low-level drive voltage line PL2 may be disposed outside the gate driver 300. In addition, the low-level drive voltage line PL2 may be connected to the anode 171 and, as such, may apply a common voltage to the anode 171. Although the gate driver 300 is simply shown in plan and cross-sectional views, the gate driver 300 may be configured using a thin film transistor TFT having the same structure as that of the thin film transistor TFT in the active area AA, And the present disclosure is not limited thereto.

The low-level drive voltage line PL2 is disposed outside the gate driver 300. The low-level drive voltage line PL2, which is disposed outside the gate driver 300, surrounds the active area AA. The low-level drive voltage line PL2 may be made of the same material as that of the source and drain electrodes 140 of the thin film transistor TFT, without being limited thereto. For example, the low-level drive voltage line PL2 may be made of the same material as that of the gate electrode 125.

In addition, the low-level drive voltage line PL2 may be electrically connected to the anode 171. The low-level drive voltage line PL2 may supply a low-level drive voltage EVSS to a plurality of pixels in the active area AA.

A touch layer 190 may be disposed on the encapsulation layer 180. In the touch layer 190, a touch buffer layer 191 thereof may be disposed between a touch sensor metal including touch electrode connection line 192 and touch electrodes 194, 195 and 196 and the cathode 173 of the light emitting element EL.

The touch buffer layer 191 may prevent a chemical solution (a developer, an etchant or the like) used in a process for manufacturing the touch sensor metal disposed on the touch buffer layer 191, external moisture, etc., from penetrating the light emitting layer 172 including an organic material. Accordingly, the touch buffer layer 191 may prevent damage to the light emitting layer 172 weak against a chemical solution or moisture.

In order to prevent damage to the light emitting layer 172 including an organic material weak against a high temperature, the touch buffer layer 191 is formed of an organic insulating material formable at a low temperature not higher than a predetermined temperature (for example, 100° C.) while having low permittivity of 1 to 3. For example, the touch buffer layer 191 may be formed of an acryl-based material, an epoxy-based material, or a siloxane-based material. The touch buffer layer 191, which is formed of an organic insulating material while having planarization performance, may prevent damage to the encapsulation layer 180 and a fracture phenomenon of the touch sensor metal formed on the touch buffer layer 191 caused by bending of the display apparatus which may be an organic light emitting display apparatus.

In accordance with a mutual capacitance-based touch sensor structure, the touch electrodes 195 and 196 are disposed on the touch buffer layer 191. In this case, the touch electrodes 195 and 196 may be disposed to cross each other.

The touch electrode connection line 192 may electrically interconnect the touch electrodes 194, 195 and 196. The touch electrode connection line 192 and the touch electrodes 195 and 196 may be disposed at different layers, respectively, under the condition that a touch insulating layer 193 is interposed therebetween. The touch electrode connection line 192 may be disposed to overlap with the bank layer 165 and, as such, may prevent a reduction in aperture ratio.

Meanwhile, a portion of the touch electrode connection line 192 may be electrically connected to a touch driving circuit (not shown) through a touch pad 198 while extending along an upper portion and a side surface of the encapsulation layer 180 and an upper portion and a side surface of the dam DAM.

The portion of the touch electrode connection line 192 may receive a touch drive signal from the touch driving circuit, may then transmit the touch drive signal to the touch electrodes 195 and 196, and may also transmit touch sensing signals from the touch electrodes 195 and 196 to the touch driving circuit.

A touch protective layer 197 may be disposed on the touch electrodes 195 and 196. Although the touch protective layer 197 are shown in the drawing as being disposed only on the touch electrodes 195 and 196, the present disclosure is not limited thereto, and the touch protective layer 197 may further extend to a region near the dam DAM or beyond the dam DAM such that the touch protective layer 197 is also disposed on the touch electrode connection line 192.

In addition, a color filter (not shown) may be further disposed on the encapsulation layer 180. The color filter may be disposed on the touch layer 190 or may be disposed between the encapsulation layer 180 and the touch layer 190.

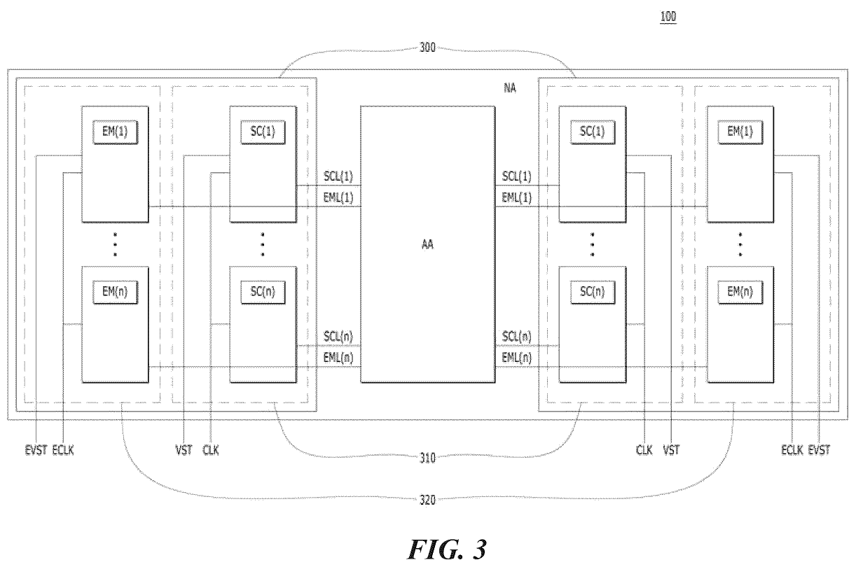

FIG. 3 is a block diagram showing a configuration of a gate driver in a display apparatus according to an exemplary embodiment of the present disclosure.

Referring to FIG. 3, a display panel 100 may include an active area AA on which an image is displayed, and a non-active area NA on which no image is displayed. The non-active area NA is disposed around the active area AA. For example, the non-active area NA may include a first non-display area located outside the active area AA in a first direction, a second non-display area located outside the active area AA in a second direction intersecting the first direction, a third non-display area located outside the active area AA in the opposite direction to the first direction, and a fourth non-display area located outside the active area AA in the direction opposite to the second direction.

An array of pixels P is disposed in the active area AA. In the non-active area NA, at least a portion of a driver may be mounted or connection thereof may be achieved. For example, in the non-active area NA, a gate driver 300 may be disposed at one side of the active area AA or may be disposed at opposite sides (for example, left and right sides) of the active area AA, as shown in FIG. 3. In the case in which gate drivers 300 are disposed at opposite sides of the non-active area NA, respectively, the gate drivers 300 are configured to have laterally symmetrical structures (mirrored structures) and, as such, it may be possible to minimize or reduce signal distortion caused by load deviations of gate lines GL. Each gate driver 300 includes a scan driver 310 configured to generate a scan signal SC, and an emission control driver 320 configured to generate an emission control signal EM.

The scan driver 310 may supply the scan signal SC to scan lines SCL in a sequential manner. The emission control driver 320 may supply the emission control signal EM to emission control lines EML in a sequential manner. The scan driver 310 may be implemented by a shift register constituted by a plurality of stages.

At one side of the active area AA, the scan driver 310 may be disposed adjacent to the active area AA, and the emission control driver 320 may be disposed outside the scan driver 310. However, the present disclosure is not limited thereto.

The scan driver 310 and the emission control driver 320 are driven by receiving respective separate start signals VST and EVST and respective separate clock signals CLK and ECLK through respective different start signal lines VSTL and respective different clock signal lines CLKL. Here, each of the start signals VST and EVST and/or the clock signals CLK and ECLK may be provided singularly or in plural.

Although respective start signal lines VSTL and respective clock signal lines CLKL of the scan driver 310 and the emission control driver 320 are shown in FIG. 3 as being disposed adjacent to the scan driver 310 or the emission control driver 320 connected thereto, the present disclosure is not limited thereto. For example, each start signal line VSTL and each clock signal line CLKL may be disposed to be adjacent to each other in an area disposed outside an area where the associated scan driver 310 or the associated emission control driver 320 is disposed.

As described above, it may be possible to provide an effect capable of reducing a bezel by simplifying a configuration of gate drivers disposed at opposite sides of an active area.

FIG. 4 is circuit diagram showing a pixel circuit in a display apparatus according to an exemplary embodiment of the present disclosure. In FIG. 4, for convenience of description, a pixel connected to an n-th pixel row (n being an integer greater than 0) is shown as an example.

Referring to FIG. 4, a pixel P in an n-th pixel row may include a driving transistor DT, a light emitting element EL connected to the driving transistor DT, and a control circuit configured to control an amount of drive current to be applied to the light emitting element EL through the driving transistor DT. For example, the control circuit may include first to seventh transistors T1 to T7, and first and second capacitors C1 and C2. Here, N is a natural number equal to or greater than 2. However, the structure of the control circuit is not limited thereto, the control circuit may include one or more transistor and one or more capacitor. For example, the control circuit may have various structures such as 4T2C, 5T2C, 6T1C, 6T2C, 7T1C, 7T2C, and the like.

In the driving transistor DT, a first electrode thereof is configured to receive a high-level drive voltage EVDD, and a second electrode thereof is connected to a third node N3. A gate electrode of the driving transistor DT is connected to a second node N2. The driving transistor DT is turned on in accordance with a voltage applied to the second node N2, thereby controlling an amount of drive current flowing through the light emitting element EL.

In the first transistor T1, a first electrode thereof is connected to a data line DL, and a second electrode thereof is connected to a first node N1. A gate electrode of the first transistor T1 is connected to a scan line SCL of the n-th pixel row and, as such, may receive an n-th scan signal SC(n). The first transistor T1 is turned on in accordance with the n-th scan signal SC(n), thereby transmitting a data voltage Vdata to the first node N1. The first transistor TI as described above may be a first switching transistor.

The first capacitor C1 is connected between the first node N1 and the second node N2. The first capacitor C1 may store a voltage corresponding to a voltage difference between the first node N1 and the second node N2. For example, the first capacitor C1 may store a voltage corresponding to a voltage difference between the data voltage Vdata applied to the data line DL and the voltage of the second node N2, and may maintain the stored voltage for one frame period, thereby stabilizing the voltage of the gate electrode of the driving transistor DT (that is, the voltage of the second node N2). The first capacitor C1 as described above may be a storage capacitor Cst.

The second transistor T2 is connected between the second node N2 and the third node N3. A gate electrode of the second transistor T2 is connected to the scan line SCL of the n-th pixel row and, as such, may receive the n-th scan signal SC(n). The second transistor T2 may be turned on in accordance with the n-th scan signal SC(n), thereby electrically interconnecting the gate electrode of the driving transistor DT (the second node N2) and the second electrode of the driving transistor DT (the third node N3). As such, the second transistor T2 may be configured to have a diode connection structure for connection of the second node N2 and the third node N3.

In another embodiment, the second transistor T2 may be constituted by a plurality of sub-transistors connected in series in order to suppress current leakage when the second transistor T2 is turned off. In such a dual gate structure, two gate electrodes are connected to each other to have the same potential, and the channel length of the dual gate structure is longer than that of a single gate structure. When the channel length increases, an increase in resistance occurs and, as such, leakage current is reduced in a turn-off state of the second transistor T2. Accordingly, operation stability may be secured. The second transistor T2 as described above may be a second switching transistor.

In the third transistor T3, a first electrode thereof is configured to receive a reference voltage Vref (to be connected to a reference voltage line VrefL), and a second electrode thereof is connected to the first node N1. A gate electrode of the third transistor T3 is connected to an emission line EL of an n+1-th pixel row and, as such, may receive an n+1-th emission control signal EM(n+1). The third transistor T3 is turned on in accordance with the n+1-th emission control signal EM(n+1), thereby transmitting the reference voltage Vref to the first node N1. The third transistor T3 as described above may be a third switching transistor.

The fourth transistor T4 is connected between the third node N3 and a fourth node N4. A gate node of the fourth transistor T4 is connected to an emission line EL of the n-th pixel row and, as such, may receive an n-th emission control signal EM(n). The fourth transistor T4 is turned on in accordance with the n-th emission control signal EM(n), thereby electrically interconnecting the driving transistor DT (the third node N3) and the light emitting element EL (the fourth node N4). The fourth transistor T4 as described above may be an emission transistor.

In the fifth transistor T5, a first electrode thereof is configured to receive an initialization voltage Vini (to be connected to an initialization voltage line ViniL), and a second electrode thereof is connected to the fourth node N4. A gate electrode of the fifth transistor T5 is connected to the scan line SCL of the n-th pixel row and, as such, may receive the n-th scan signal SC(n). The fifth transistor T5 is turned on in accordance with the n-th scan signal SC(n), thereby applying the initialization voltage Vini to an anode 171 of the light emitting element EL (the fourth node N4). The fifth transistor T5 as described above may be a first initialization transistor.

In the sixth transistor T6, a first electrode thereof is configured to receive the reference voltage Vref, and a second electrode thereof is connected to the second node N2. A gate electrode of the sixth transistor T6 is connected to a scan line SCL of an n−1-th pixel row and, as such, may receive an n−1-th scan signal SC(n−1). The sixth transistor T6 is turned on in accordance with the n−1-th scan signal SC(n−1), thereby applying the reference voltage Vref to the gate electrode of the driving transistor DT (the second node N2). The sixth transistor T6 as described above may be a second initialization transistor.

The second capacitor C2 is connected between the fourth node N4 and a low-level drive voltage line PL2 to which a low-level drive voltage EVSS is applied. The second capacitor C2 may be configured to form a capacitance between the anode 171 and a cathode 173 of the light emitting element EL. The second capacitor C2 as described above may be a parasitic capacitor Coled of the light emitting element EL. Since the second capacitor C2 is the parasitic capacitor Coled, and the first capacitor C1 is the storage capacitor Cst, the first capacitor C1 may have a greater capacitance than the second capacitor C2.

In the second transistor T7, a first electrode thereof is connected to the fourth node N4, and a second electrode thereof is connected to the initialization voltage line ViniL. A gate electrode of the seventh transistor T7 is connected to a sensing signal line SL and, as such, may receive a sensing signal Sen. The seventh transistor T7 is turned on in accordance with the sensing signal Sen, thereby forming a current path between a sensing unit 700 and the second capacitor C2. Accordingly, the sensing unit 700 may sense a charge amount stored in the second capacitor C2. The seventh transistor T7 as described above may be a sensing transistor.

In the light emitting element EL, the anode 171 thereof may be connected to the fourth node N4, and the cathode 173 thereof may be connected to the low-level drive voltage EVSS. When the driving transistor DT and the fourth transistor T4 are turned on, a current path is formed between the high-level drive voltage EVDD and the low-level drive voltage EVSS and, as such, drive current may flow through the light emitting element EL. The light emitting element EL may emit light at a brightness corresponding to an amount of drive current applied thereto.

In the exemplary embodiment shown in FIG. 4, the pixel P includes a low-temperature polysilicon (LTPS) thin film transistor. The LTPS thin film transistor includes a gate electrode, a source electrode, and a drain electrode. The LTPS thin film transistor includes an active layer formed of polysilicon. Such an LTPS thin film transistor may be constituted by a P-type thin film transistor. The LTPS thin film transistor has high electron mobility and, as such, has rapid-driving characteristics. However, this exemplary embodiment is not limited to the above-described conditions.

In another embodiment, at least one of the transistors DT, T1 to T5, or T6 may be constituted by an oxide semiconductor thin film transistor. The oxide semiconductor thin film transistor includes a gate electrode, a source electrode, and a drain electrode. The oxide semiconductor thin film transistor includes an active layer formed of oxide semiconductor. Here, the oxide semiconductor may be amorphous or crystalline oxide semiconductor. The oxide semiconductor thin film transistor may be constituted by an N-type transistor. The oxide semiconductor thin film transistor may be manufactured through a low-temperature process, and has low charge mobility, as compared to the LTPS thin film transistor. The oxide semiconductor thin film transistor as described above exhibits excellent off-current characteristics.

The reference voltage line VrefL may be formed at the same layer as a source or drain electrode 140 of the transistor TFT, using the same material as that of the source or drain electrode 140. However, the present disclosure is not limited to the above-described condition, and at least a portion of the reference voltage line VrefL may be formed at the same layer as a gate electrode 125, using the same material as that of the gate electrode 125, may be formed at the same layer as touch electrodes 194, 195, and 196, using the same material as that of the touch electrodes 194, 195, and 196, or may be formed at the same material as a semiconductor layer 115, using the same material as that of the semiconductor layer 115. In addition, at least a portion of the reference voltage line VrefL may be formed at the same layer as a shield metal layer not shown in the drawing, using the same material as that of the shield metal layer.

As described above, it may be possible to prevent failure caused by short circuit possibly generated in a pixel during driving, and to achieve an enhancement in image quality through sensing and compensation of degradation of a light emitting element.

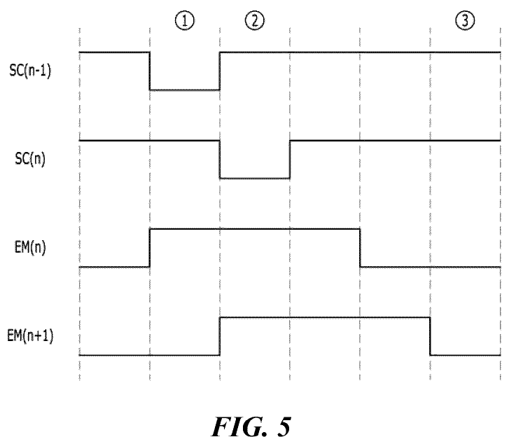

FIG. 5 is a diagram depicting operation waveforms of the pixel circuit shown in FIG. 4 in a display mode of the display apparatus according to the exemplary embodiment of the present disclosure.

Referring to FIG. 5, each of the plurality of pixels P may perform an initialization operation, a programming operation, and an emission operation in accordance with a scan signal SC and an emission control signal EM.

During an initialization period \textcircled{1} in which an initialization operation is performed, the pixel circuit may initialize particular nodes therein to a reference voltage Vref, for stability of operation.

During a programming period \textcircled{2} in which a programming operation is performed, the pixel circuit may program a gate-source voltage of the driving transistor DT based on a data voltage Vdata. During the programming period \textcircled{2}, a threshold voltage of the driving transistor DT may be sampled and compensated.

During an emission period \textcircled{3} in which an emission operation is performed, drive current corresponding to the gate-source voltage flows between the source and drain electrodes of the driving transistor DT, and the light emitting element EL emits light by the drive current. In accordance with the emission control signal EM, the emission transistor may be turned on during the initialization period \textcircled{1} and the emission period \textcircled{3} while being turned off during the programming period \textcircled{1}.

In the exemplary embodiment of the present disclosure, the driving mode in which the pixel P performs the initialization operation, the programming operation, and the emission operation is referred to as a “display mode.”

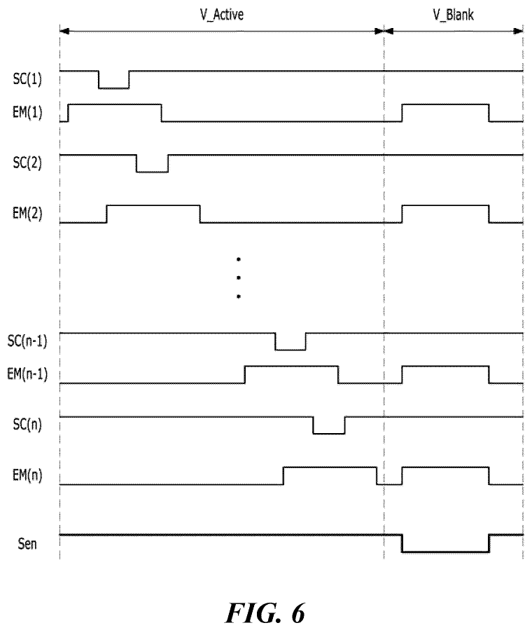

The pixel P according to the exemplary embodiment of the present disclosure further performs a sensing mode in which degradation of the light emitting element EL is sensed, in addition to the display mode. Operation of the pixel P in the sensing mode will be described later in detail with reference to FIG. 6.

First, referring to FIG. 5, one frame may include the initialization period \textcircled{1}, the programming period \textcircled{2}, and the emission period \textcircled{3}.

In the initialization period \textcircled{1}, an n+1-th emission control signal EM(n+1) of a turn-on level is applied, thereby turning on the third transistor T3, and an n−1-th scan signal SC(n−1) of a turn-on level is applied, thereby turning on the sixth transistor T6. Accordingly, during the initialization period \textcircled{1}, the reference voltage Vref is applied to the first node N1 and the second node N2. In this case, the driving transistor DT may be turned on as the reference voltage Vref is applied to the second node N2 connected to the gate electrode of the driving transistor DT. However, the fourth transistor T4 is in a turn-off state and, as such, the second electrode of the driving transistor DT connected to the third node N3 may be in a floated state during the initialization period \textcircled{1}. Accordingly, during the initialization period \textcircled{1}, both ends of the first capacitor C1 may be initialized to the reference voltage Vref.

In the programming period \textcircled{2}, the n+1-th emission control signal EM(n+1) and the n−1-th scan signal SC(n−1) transition to a turn-off level and, as such, the third transistor T3 and the sixth transistor T6 are turned off, whereas the first transistor T1, the second transistor T2, and the fifth transistor T5 are turned on in accordance with application of an n-th scan signal SC(n) of a turn-on level thereto. Accordingly, during the programming period \textcircled{2}, the data voltage Vdata applied to the data line DL is applied to the first node N1, and the initialization voltage Vini applied to the initialization voltage line ViniL is applied to the fourth node N4.

In addition, a charged voltage of the first capacitor C1 may gradually reach a voltage corresponding to a difference between the data voltage Vdata and the reference voltage Vref. When the charged voltage of the first capacitor C1 is transmitted to the gate electrode of the driving transistor DT, a source-gate voltage of the driving transistor DT becomes greater than a threshold voltage Vth of the driving transistor DT and, as such, the driving transistor DT may be turned on. In this case, the source-drain current of the driving transistor DT may be determined in accordance with the data voltage Vdata, the reference voltage Vref, and the threshold voltage Vth of the driving transistor DT. The driving transistor DT may supply the source-drain current to the third node N3 until the source-gate voltage of the driving transistor DT reaches the threshold voltage Vth of the driving transistor DT. In addition, the second transistor T2 may supply the voltage of the third node N3 to the second node N2.

During the turn-on period of the driving transistor DT, the voltage of the second node N2 and the source-drain current of the driving transistor DT may be varied in the above-described manner, and the voltage of the second node N2 may converge on a difference voltage between the data voltage Vdata and the threshold voltage Vth of the driving transistor DT.

Meanwhile, during the programming period (2), the anode 171 of the light emitting element EL may be initialized to the initialization voltage Vini, corresponding to the voltage of the fourth node N4 because the initialization voltage Vini is applied to the fourth node N4 through the fifth transistor T5. Accordingly, during the programming period (2), the second capacitor C2 may be initialized to the initialization voltage Vini.

A hold period may be further included between the programming period \textcircled{2} and the emission period \textcircled{3}. During the hold period, the n-th scan signal SC(n) transitions to a turn-off level and, as such, the first transistor T1, the second transistor T2, and the fifth transistor T5 are turned off. During the hold period, the voltage of the second node N2 may be stably maintained through the first capacitor C1.

In the emission period \textcircled{3}, an n-th emission control signal EM(n) of a turn-on level and the n+1-th emission control signal EM(n+1) of the turn-on level are applied and, as such, the third transistor T3 and the fourth transistor T4 are turned on, and a current path extending from the high-level drive voltage EVDD to the light emitting element EL via the driving transistor DT is formed. During the emission period \textcircled{3}, the reference voltage Vref is applied to the first node N1 through the turned-on third transistor T3. In this case, both ends of the first capacitor C1 are coupled to each other and, as such, the voltage of the second node N2 may be FIG. 6 is a diagram depicting operation waveforms in an active period in which the display mode operates and a blank period in which the sensing mode operates, for one frame, in the display apparatus according to the exemplary embodiment of the present disclosure.

Referring to FIG. 6, in the display mode operating during an active period V_Active, a scan signal SC and an emission control signal EM are sequentially applied to the plurality of pixels and, as such, the plurality of pixels operates to display an image on the display panel 100.

A sensing signal Sen may be applied at a turn-off level during the active period V_Active in which the display mode operates.

In the sensing mode operating during a blank period V_Blank, a sensing signal Sen of a turn-on level is applied through the sensing signal line SL and, as such, the seventh transistor T7 may be turned on. Accordingly, the sensing unit 700 may sense a charge amount stored in the second capacitor C2 through a current path formed through the initialization voltage line ViniL.

In other words, the second capacitor C2 forms a capacitance between the anode 171 and the cathode 173 of the light emitting element EL, and the charge amount stored in the second capacitor C2 may be varied in accordance with a degradation degree of the light emitting element EL. Accordingly, it may be possible to sense a degradation degree of the light emitting element EL by sensing the charge amount of the second capacitor C2.

In addition, during the blank period V_Blank, scan signals SC and emission control signals EM of all pixel rows operate at a turn-off level, and the sensing signal Sen may have a phase inverted with respect to a phase of the emission control signal EM.

FIGS. 7A and 7B are diagrams showing a configuration of the controller including the sensing unit in the display apparatus according to the exemplary embodiment of the present disclosure.

Referring to FIGS. 7A and 7B, each of the initialization voltage line ViniL and the sensing signal line SL in the display panel 100 may be configured to include a horizontal line and a vertical line and, as such, may be connected to a plurality of pixels P. In this case, the initialization voltage line ViniL may operate to initialize the light emitting element El in the display mode by applying the initialization voltage Vini to the fourth node N4 through the power supply 500, whereas the initialization voltage line ViniL may operate to sense a charge amount of the second capacitor C2 through the sensing unit 700 in the sensing mode, thereby sensing a degradation state of the light emitting element EL.

The initialization voltage line ViniL and/or the sensing signal line SL is branched into vertical lines through a horizontal line formed at one side of the display panel 100, and all initialization voltage lines ViniL in the display panel 100 may be electrically interconnected. Accordingly, in the sensing mode, the sensing unit 700 may obtain an analog sensing voltage Vsen by directly sensing current flowing through all light emitting elements EL.

The initialization voltage line ViniL and/or the sensing signal line SL may be formed at the same layer as the source or drain electrode 140 of the transistor TFT, using the same material as that of the source or drain electrode 140 of the transistor TFT. Of course, the present disclosure is not limited to the above-described conditions, and at least a portion of the initialization voltage line ViniL and/or the sensing signal line SL may be formed at the same layer as the gate electrode 125, using the same material as that of the gate electrode 125, may be formed at the same layer as the touch electrodes 194, 195, and 196, using the same material as that of the touch electrodes 194, 195, and 196, or may be formed at the same layer as the semiconductor layer 115, using the same material as that of the semiconductor layer 115. In addition, at least a portion of the initialization voltage line ViniL and/or the sensing signal line SL may be formed at the same layer as a shield metal layer not shown in the drawings, using the same material as that of the shield metal layer.

The sensing unit 700 may be configured to include a current integrator 710 and an analog-to-digital converter (referred to as an “ADC” hereinafter) 720. The current integrator 710 includes an amplifier AMP including an inverting input terminal (−) configured to receive pixel current of the light emitting element EL from the initialization voltage line ViniL, a non-inverting input terminal (+) configured to receive an initialization voltage Vpre, and an output terminal, an integrating capacitor Cfb connected between the inverting input terminal (−) and the output terminal of the amplifier AMP, and a reset switch RST connected to both ends of the integrating capacitor Cfb. The current integrator 710 is connected to the ADC 720 and, as such, supplies an analog sensing voltage Vsen output from the amplifier AMP of the current integrator 710 to the ADC 720.

In an exemplary embodiment of FIG. 7A, the sensing unit 700 may be disposed on a printed circuit board (PCB), together with the controller 200 and, as such, may sense, at once, current flowing through all light emitting elements EL disposed in the display panel 100. Alternatively, as in an exemplary embodiment of FIG. 7B, the sensing unit 700 may be configured in each of a plurality of driver-integrated circuits (D-ICs) included in the data driver 400. In this case, a plurality of sensing units 700 may be configured to be equal in number to the D-ICs. Each sensing unit 700 senses only an area of the display panel 100 driven by one D-IC and, as such, may more densely sense a degradation degree of the light emitting elements EL.

In addition, the sensing unit 700 may simultaneously process a plurality of analog sensing voltages Vsen in parallel, using a plurality of ADCs or may sequentially process a plurality of analog sensing voltages Vsen in series, using one ADC. The ADCs in parallel processing are advantageous in that accuracy of sensing is enhanced, as compared to the ADC in serial processing. Such an ADC may be implemented by a flash type ADC, an ADC using a tracking technology, a successive approximation register (SART) type ADC, or the like. The ADC 720 converts an analog sensing voltage Vsen supplied from the current integrator 710 into digital sensing data, and then transmits the digital sensing data to the controller 200.

The controller 200 may analyze the digital sensing data and, as such, may output compensation data according to an accumulated degradation degree of the light emitting element EL. In this case, the compensation data may be determined using one of a plurality of look-up tables (LUTs) stored in a memory. In other words, the controller 200 may compensate for degradation of the light emitting element EL by selecting a suitable one of the LTUs in accordance with a degradation level of the light emitting element EL. Thus, it may be possible to minimize or reduce a compensation error by sensing degradation of the light emitting element EL, and compensating for the sensed degradation using the plurality of LUTs.

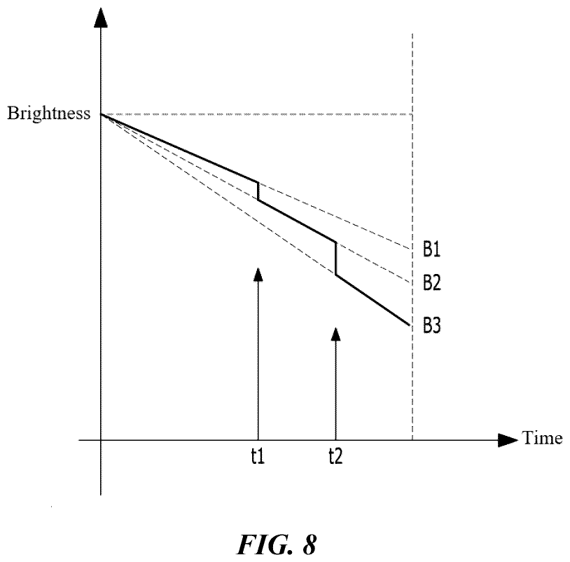

FIG. 8 is a graph depicting a lifespan brightness in the display apparatus according to the exemplary embodiment of the present disclosure.

As described above, the sensing mode may operate in every blank period V_Blank of all frames. Of course, the sensing mode is not limited to the above-described condition, and may be performed to be activated at a particular time.

In other words, in the sensing mode, the sensing signal Sen transitions to a turn-on level after the display apparatus 10 is driven for a previously-set time, and again transitions to a turn-off level after sensing and compensation of the light emitting element EL are completed. For all frames, these procedures may be repeated. That is, the sensing mode may be activated only at the previously-set time, and may operate to sense degradation of the light emitting element EL by applying a sensing signal Sen of a turn-on level during the blank period V_Blank, thereby turning on the seventh transistor T7 and, as such, forming a current path.

In this case, the controller 200 may further include a data counter (not show) therein. The data counter may accumulate data such as an image signal, a synchronization signal, or the like, thereby counting a driving time of the display panel 100, and may operate to output a sensing signal Sen at a particular time.

In other words, the display apparatus 10 may drive the light emitting element EL at a brightness intensity corresponding to a first lifespan brightness B1 at an initial driving time. The display apparatus 10 may then apply a sensing signal Sen of a turn-on level at a first sensing time t1, thereby sensing degradation of the light emitting element EL and compensating for the sensed degradation, and, as such, may drive the light emitting element EL at a second lifespan brightness B2. Similarly, the display apparatus 10 may drive the light emitting element EL at a third lifespan brightness B3 at a second sensing time t2. In this case, the first sensing time t1 may be a time after at least 2,000 hours have elapsed.

For example, as shown in FIG. 8, the display apparatus 10 may drive the light emitting element EL at a brightness intensity corresponding to a first lifespan brightness B1 before the first sensing time t1, the display apparatus 10 may drive the light emitting element EL at a second lifespan brightness B2 which is lower than the first lifespan brightness B1 between the first sensing time t1 and the second sensing time t2, and the display apparatus 10 may drive the light emitting element EL at a third lifespan brightness B3 which is lower than the second lifespan brightness B2 from a second sensing time t2. However, the present disclosure is not limited thereto.

As apparent from the above description, through the pixel circuit according to the exemplary embodiment of the present disclosure, it may be possible to prevent failure caused by short circuit possibly generated during driving, to enhance lifespan reliability through degradation sensing and compensation using the initialization voltage line ViniL, and to avoid mura defects such as horizontal stripes caused by a brightness difference between the active period V_Active and the blank period V_Blank.

In addition, each of the gate drivers 300 disposed at opposite sides of the active area AA is configured through inclusion of one scan driver 310 and one emission control driver 320 and, as such, the bezel area BZ including the non-active area NA may be designed to have a small area.

The display apparatus according to the exemplary embodiment of the present disclosure may be explained as follows.

The display apparatus according to the exemplary embodiment of the present disclosure may include a display panel with a plurality of data lines, a plurality of gate lines, and a plurality of subpixels disposed thereon, the display panel being configured to operate in a display mode for display of an image and a sensing mode for sensing of degradation of the pixels, a gate driver configured to supply a scan signal and an emission control signal to the plurality of gate lines, a data driver configured to supply a data signal to the plurality of data lines, a power supply configured to apply an initialization voltage to the pixels in the sensing mode, and a sensing unit configured to sense degradation of the pixels in the sensing mode.

The display apparatus according to the exemplary embodiment of the present disclosure may include a light emitting element. a capacitor connected between a first node and a second node, a first transistor including a first electrode connected to a reference voltage line and a second electrode connected to the first node, the first transistor being configured to supply a reference voltage to the first node in response to an emission control signal of an n+1-th pixel row, a second transistor including a first electrode connected to the reference voltage line and a second electrode connected to the second node, the second transistor being configured to supply the reference voltage to the second node in response to a scan signal of an n−1-th pixel row, and a driving transistor connected, at a gate electrode thereof, to the second node, the driving transistor including a first electrode configured to receive a high-level drive voltage and a second electrode connected to a third node.

The display apparatus according to the exemplary embodiment of the present disclosure may further include a third transistor including a first electrode connected to an initialization voltage line and a second electrode connected to a fourth node, the third transistor being configured to supply an initialization voltage to the fourth node in response to a scan signal of an n-th pixel row, and a second capacitor connected to the fourth node at one end thereof while being connected to a low-level drive voltage line at the other end thereof.

The display apparatus according to the exemplary embodiment of the present disclosure may further include a fourth transistor including a first electrode connected to the initialization voltage line and a second electrode connected to the one end of the second capacitor, the fourth transistor being configured to be turned on in response to a sensing signal.

According to the display apparatus according to the exemplary embodiment of the present disclosure, the first capacitor may have a greater capacitance than the second capacitor.

The display apparatus according to the exemplary embodiment of the present disclosure may further include a fifth transistor comprising a first electrode connected to a data line and a second electrode connected to the first node, the fifth transistor being configured to be turned on in response to the scan signal of the n-th pixel row, so as to transmit a data voltage to the first node.

The display apparatus according to the exemplary embodiment of the present disclosure may further include a sixth transistor connected between the second node and the third node, the sixth transistor being configured to be turned on in response to the scan signal of the n-th pixel row, so as to electrically interconnect the gate electrode of the driving transistor and the second electrode of the driving transistor.

The display apparatus according to the exemplary embodiment of the present disclosure may further include a seventh transistor connected between the third node and the fourth node, the seventh transistor being configured to be turned on in response to an emission control signal of an n-th pixel row, so as to interconnect the driving transistor and the light emitting element.

In the display apparatus according to the exemplary embodiment of the present disclosure, the fourth transistor may operate only in the sensing mode.

In the display apparatus according to the exemplary embodiment of the present disclosure, the gate driver may include one scan driver and one emission control driver respectively disposed at opposite sides of an active area.

In the display apparatus according to the exemplary embodiment of the present disclosure, the gate driver may receive a gate control signal through a level shifter.

In the display apparatus according to the exemplary embodiment of the present disclosure, the sensing unit may be disposed on a printed circuit board.

In the display apparatus according to the exemplary embodiment of the present disclosure, the data driver may include a plurality of driver-integrated circuits (D-ICs), and the sensing unit may be configured to be included in each of the plurality of D-ICs to sense the display panel on a block basis.

In the display apparatus according to the exemplary embodiment of the present disclosure, at least one of a reference voltage line, an initialization voltage line, or a sensing signal line may be disposed at the same layer as a high-level drive voltage line or the data lines.

In the display apparatus according to the exemplary embodiment of the present disclosure, at least one of the reference voltage line, an initialization voltage line, or a sensing signal line may be formed of a material identical to a material of the first and second electrodes of the driving transistor.

In the display apparatus according to the exemplary embodiment of the present disclosure, at least two of the reference voltage line, an initialization voltage line, and a sensing signal line may be parallel.

In the display apparatus according to the exemplary embodiment of the present disclosure, one frame may be configured to include an active period for display of an image and a blank period except for the active period, the display mode may operate in the active period, and the sensing mode may operate in the blank period.

In the display apparatus according to the exemplary embodiment of the present disclosure, the sensing unit may sense pixel degradation through a sensing signal output at a previously-set time.

In the display apparatus according to the exemplary embodiment of the present disclosure, the controller may count a driving time of the display panel through accumulation of data, and may output a sensing signal at a previously-set time.

The display apparatus according to the exemplary embodiment of the present disclosure may include a light emitting element, a capacitor connected between a first node and a second node, a first transistor including a first electrode connected to a reference voltage line and a second electrode connected to the first node, the first transistor being configured to supply a reference voltage to the first node in response to an emission control signal of an n+1-th pixel row, a second transistor including a first electrode connected to the reference voltage line and a second electrode connected to the second node, the second transistor being configured to supply the reference voltage to the second node in response to a scan signal of an n−1-th pixel row, a driving transistor connected, at a gate electrode thereof, to the second node, the driving transistor including a first electrode configured to receive a high-level drive voltage and a second electrode connected to a third node, a third transistor including a first electrode connected to an initialization voltage line and a second electrode connected to a fourth node, the third transistor being configured to supply an initialization voltage to the fourth node in response to a scan signal of an n-th pixel row, and a fourth transistor including a first electrode connected to the initialization voltage line and a second electrode connected to the fourth node, the fourth transistor being configured to be turned on in response to a sensing signal.

A controlling method of pixel circuit according to the exemplary embodiment of the present disclosure, the pixel circuit including a first transistor, a second transistor, a driving transistor, a third transistor, a fourth transistor and a first capacitor, the controlling method may comprises: supplying a reference voltage to a first node via a first transistor in response to an emission control signal of an n+1-th pixel row, the first transistor comprising a first electrode connected to a reference voltage line and a second electrode connected to the first node; supplying the reference voltage to a second node via a second transistor in response to a scan signal of an n−1-th pixel row, the second transistor comprising a first electrode connected to the reference voltage line and a second electrode connected to the second node; receiving a high-level drive voltage via a driving transistor, the driving transistor comprising a first electrode receiving the high-level drive voltage, and a second electrode connected to a third node, and a gate electrode connected to the second node; supplying an initialization voltage to a fourth node via a third transistor in response to a scan signal of an n-th pixel row, the third transistor comprising a first electrode connected to an initialization voltage line and a second electrode connected to the fourth node; and turning on a fourth transistor in response to a sensing signal, the fourth transistor comprising a first electrode connected to the initialization voltage line and a second electrode connected to the fourth node, wherein a first capacitor is connected between the first node and the second node.

As apparent from the above description, in accordance with the exemplary embodiment of the present disclosure, it may be possible to prevent failure caused by short circuit possibly generated in a pixel during driving, and to achieve an enhancement in image quality through sensing and compensation of degradation of a light emitting element.

In addition, it may be possible to provide an effect capable of reducing a bezel by simplifying a configuration of gate drivers disposed at opposite sides of an active area.

Effects according to the exemplary embodiments of the disclosure are not limited to the above-illustrated contents, and wider variety of effects may be included in the specification.

Features, structures, or effects described in the foregoing exemplary embodiment are included in at least one exemplary embodiment of the present disclosure, and are not necessarily limited to only one exemplary embodiment thereof. Further, the features, structures, or effects exemplified in each exemplary embodiment may be combined or modified by those skilled in the art and implemented to other embodiments thereof. Therefore, descriptions related to such combinations and modifications will be construed as being included in the scope of the present disclosure.

It is apparent that the present disclosure described above is not limited to the above-described embodiments and the accompanying drawings, and those skilled in the art will appreciate that various modifications, changes and substitutions are possible, without departing from the scope and spirit of the present disclosure. All changes or modifications derived from the meaning and scope of the claims and their equivalents should be construed as being included in the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display panel with a plurality of data lines, a plurality of gate lines, and a plurality of pixels disposed thereon, the display panel being configured to operate in a display mode or a sensing mode;
a gate driver configured to supply a scan signal and an emission control signal to the plurality of gate lines;
a data driver configured to supply a data signal to the plurality of data lines;
a power supply configured to apply an initialization voltage to the plurality of pixels in the sensing mode; and
a sensing unit configured to sense degradation of the plurality of pixels in the sensing mode.

2. The display apparatus according to claim 1, wherein, among the plurality of pixels, each pixel of an n-th pixel row comprises:
a light emitting element;
a first capacitor connected between a first node and a second node;
a first transistor comprising a first electrode connected to a reference voltage line and a second electrode connected to the first node, the first transistor being configured to supply a reference voltage to the first node in response to an emission control signal of an n+1-th pixel row;
a second transistor comprising a first electrode connected to the reference voltage line and a second electrode connected to the second node, the second transistor being configured to supply the reference voltage to the second node in response to a scan signal of an n−1-th pixel row; and
a driving transistor comprising a gate electrode connected to the second node, a first electrode configured to receive a high-level drive voltage and a second electrode connected to a third node,
wherein n is an integer greater than 1.

3. The display apparatus according to claim 2, wherein the pixel further comprises:
a third transistor comprising a first electrode connected to an initialization voltage line and a second electrode connected to a fourth node, the third transistor being configured to supply the initialization voltage to the fourth node in response to a scan signal of an n-th pixel row; and
a second capacitor connected between the fourth node and a low-level drive voltage line.

4. The display apparatus according to claim 3, wherein the pixel further comprises:
a fourth transistor comprising a first electrode connected to the initialization voltage line and a second electrode connected to the one end of the second capacitor, the fourth transistor being configured to be turned on in response to a sensing signal.

5. The display apparatus according to claim 4, wherein the first capacitor has a greater capacitance than the second capacitor.

6. The display apparatus according to claim 4, wherein the pixel further comprises:
a fifth transistor comprising a first electrode connected to a data line and a second electrode connected to the first node, the fifth transistor being configured to be turned on in response to the scan signal of the n-th pixel row, so as to transmit a data voltage to the first node.

7. The display apparatus according to claim 6, wherein the pixel further comprises:
a sixth transistor connected between the second node and the third node, the sixth transistor being configured to be turned on in response to the scan signal of the n-th pixel row, so as to electrically interconnect the gate electrode of the driving transistor and the second electrode of the driving transistor.

8. The display apparatus according to claim 7, wherein the pixel further comprises:
a seventh transistor connected between the third node and the fourth node, the seventh transistor being configured to be turned on in response to an emission control signal of an n-th pixel row, so as to interconnect the driving transistor and the light emitting element.

9. The display apparatus according to claim 4, wherein the fourth transistor is configured to operate only in the sensing mode.

10. The display apparatus according to claim 4, wherein at least one of the reference voltage line, the initialization voltage line, or a sensing signal line for supplying the sensing signal is disposed at a same layer as a high-level drive voltage line for supplying the high-level drive voltage or the data lines.

11. The display apparatus according to claim 4, wherein at least one of the reference voltage line, the initialization voltage line, or a sensing signal line for supplying the sensing signal is formed of a material same as a material of the first and second electrodes of the driving transistor.

12. The display apparatus according to claim 4, wherein at least two of the reference voltage line, the initialization voltage line, or a sensing signal line for supplying the sensing signal are parallel.

13. The display apparatus according to claim 1, wherein the gate driver comprises one scan driver and one emission control driver respectively disposed at opposite sides of an active area.

14. The display apparatus according to claim 13, wherein the emission control driver is disposed outside the scan driver.

15. The display apparatus according to claim 1, wherein the gate driver is connected to receive a gate control signal through a level shifter.

16. The display apparatus according to claim 1, wherein the sensing unit is disposed on a printed circuit board.

17. The display apparatus according to claim 1, wherein:
the data driver comprises a plurality of driver-integrated circuits; and
the sensing unit is comprised in each of the plurality of driver-integrated circuits to sense the display panel on a block basis.

18. The display apparatus according to claim 1, wherein:
one frame of the display apparatus comprises an active period for display the image and a blank period except for the active period;
the display mode operates in the active period; and
the sensing mode operates in the blank period.

19. The display apparatus according to claim 1, wherein the sensing unit is configured to sense pixel degradation through a sensing signal output at a previously-set time.

20. The display apparatus according to claim 19, further comprising; a controller for counting a driving time of the display panel through accumulation of data, and outputting the sensing signal at the previously-set time.

21. A pixel circuit comprising:
a light emitting element;
a first capacitor connected between a first node and a second node;
a first transistor comprising a first electrode connected to a reference voltage line and a second electrode connected to the first node, the first transistor being configured to supply a reference voltage to the first node in response to an emission control signal of an n+1-th pixel row;
a second transistor comprising a first electrode connected to the reference voltage line and a second electrode connected to the second node, the second transistor being configured to supply the reference voltage to the second node in response to a scan signal of an n−1-th pixel row;
a driving transistor comprising a gate electrode connected to the second node, a first electrode configured to receive a high-level drive voltage and a second electrode connected to a third node;
a third transistor comprising a first electrode connected to an initialization voltage line and a second electrode connected to a fourth node, the third transistor being configured to supply an initialization voltage to the fourth node in response to a scan signal of an n-th pixel row; and
a fourth transistor comprising a first electrode connected to the initialization voltage line and a second electrode connected to the fourth node, the fourth transistor being configured to be turned on in response to a sensing signal.

22. The pixel circuit according to claim 21, wherein the fourth transistor is configured to operate only in a sensing mode.

23. The pixel circuit according to claim 21, further comprising:
a second capacitor connected between the fourth node and a low-level drive voltage line.

24. The pixel circuit according to claim 23, wherein the first capacitor has a greater capacitance than the second capacitor.

25. A controlling method of pixel circuit, the pixel circuit including a first transistor, a second transistor, a driving transistor, a third transistor, a fourth transistor and a first capacitor, the controlling method comprising:
supplying a reference voltage to a first node via the first transistor in response to an emission control signal of an n+1-th pixel row, the first transistor comprising a first electrode connected to a reference voltage line and a second electrode connected to the first node;
supplying the reference voltage to a second node via the second transistor in response to a scan signal of an n−1-th pixel row, the second transistor comprising a first electrode connected to the reference voltage line and a second electrode connected to the second node;
receiving a high-level drive voltage via the driving transistor, the driving transistor comprising a first electrode receiving the high-level drive voltage, and a second electrode connected to a third node, and a gate electrode connected to the second node;
supplying an initialization voltage to a fourth node via the third transistor in response to a scan signal of an n-th pixel row, the third transistor comprising a first electrode connected to an initialization voltage line and a second electrode connected to the fourth node; and
turning on the fourth transistor in response to a sensing signal, the fourth transistor comprising a first electrode connected to the initialization voltage line and a second electrode connected to the fourth node,
wherein the first capacitor is connected between the first node and the second node.

26. The controlling method according to claim 25, wherein the fourth transistor operates only in a sensing mode.

27. The controlling method according to claim 25, wherein a second capacitor is connected between the fourth node and a low-level drive voltage line.

28. The controlling method according to claim 27, wherein the first capacitor has a greater capacitance than the second capacitor.
